(19) United States
(12) Patent Application Publication
(10) Pub. No.: US 2007/0222524 A1
(43) Pub. Date: Sep. 27, 2007

(54) Antenna Amplfier

(76) Inventors: Gerhard Kottschlag, Hildesheim (DE); Jen Passoke, Hemmingen (DE)

Correspondence Address: KENYON & KENYON LLP, ONE BROADWAY, NEW YORK, NY, 10004, US

(21) Appl. No.: 10/576,242

(22) PCT Filed: Sep. 17, 2004
(86) PCT No.: PCT/EP04/52220

§ 371 Date: Jan. 19, 2007

(30) Foreign Application Priority Data
Nov. 8, 2003 (DE) 103 52 290.5

(51) Int. Cl. H03F 3/04; H01Q 23/00; H03F 3/191

(52) U.S. Cl. 330/305

(57) ABSTRACT

An antenna amplifier includes at least one input for connecting to an antenna and at least one output for connecting to a receiver, as well as at least one means of signal-level matching positioned between the input and the output. The antenna amplifier improves the noise-to-useful signal ratio, in particular in situations in which a noise signal having a high level is applied, by providing a narrow-band filter situated between the input and the means of signal-level matching, with the mid-frequency of the filter passband being able to be changed and tuned to the receive channel of the receiver.

### FIELD OF THE INVENTION

The present invention relates to an antenna amplifier and a receiver.

### BACKGROUND INFORMATION

In motor vehicles, the signal path of a radio receiving system is often made up of an antenna, an impedance matcher and/or amplifier, as well as a receiving part. In the element for impedance matching, which is normally situated near the base point of the antenna, the impedance of the signal received by the antenna is actively or passively converted to a new rated impedance. This allows, inter alia, broadband matching to the subsequent element in the signal path, in this case the receiver. An active impedance matcher, i.e., an element for impedance matching, which is used for amplification as well, allows the signal received by the antenna to be simultaneously amplified, e.g., in order to compensate for losses in the antenna line between the active impedance matcher and the receiver. The element for impedance matching and/or amplification is referred to in the following as an antenna amplifier.

Conventional, active antenna amplifiers are operated with a high bandwidth, i.e., the signals of the entire receiving band are applied to the active component. One of the disadvantages in using active components in the antenna amplifier is their nonlinear behavior, which has a particularly disruptive effect on the receiving capacity, when the base voltages of the antenna are large due to high field intensities. In order to limit the nonlinear effects in the antenna amplifier, the level is reduced with the aid of an automatic control system. If the level of any signal in the range of reception is higher than the operating level of this control circuit, then the level of the signal in the basic channel, which may have a considerably lower level than the interference signals having the highest level, may be considerably reduced by the control system. This markedly deteriorates the reception quality of the desired basic channel.

An object of the present invention is to improve the noise-to-useful signal ratio, in particular in situations in which an interference signal having a high level is applied.

### SUMMARY

An antenna amplifier, a receiver, as well as a receiving system are provided in accordance with the present invention. In the case of the antenna amplifier of the present invention, it is provided that a narrow-band filter be situated between the input and the means of signal-level matching, the mid-frequency of the filter passband being able to be changed and tuned to the receive channel of the receiver.

The information regarding which channel or frequency the desired receiving frequency is, is present in the receiving part. This information is now used to control a narrow-band filter in the antenna amplifier in such a manner that the deterioration of the basic channel is largely prevented. The filter is situated in the signal path, in front of the active amplifier element of the antenna amplifier. In each instance, the passband of the narrow-band filter is adjusted to the frequency of the desired basic channel. This reduces the signal level of the unwanted frequencies and increases the received power of the entire system. In this context, it may be provided that the pass frequency of the filter be tunable via a tuning signal, which is applied to a control terminal of the antenna amplifier and generated by the receiver. Therefore, information items necessary for tuning the filter are transmitted over separate lines. As an alternative, it is provided that the pass frequency of the filter be tunable via a tuning signal, which is applied to the output of the antenna amplifier and generated by the receiver. In this context, the tuning signal, which is applied to the output of the antenna amplifier and evaluated in the antenna amplifier, may be a d.c. voltage or an analog signal, e.g., amplitude-modulated, frequency-modulated, or pulse-width-modulated signal, or a digital data stream. In this connection, the voltage supply, which may utilize the antenna line as well, may have to be taken into account. In this case, the antenna amplifier may include a device for splitting up or filtering out the signal components at the output. In a further refinement, a supply voltage for the antenna amplifier may be applied to the output of the antenna amplifier. In this case, the impedance-matched and amplified, useful signal of the antenna, the tuning signal, and the supply voltage are therefore transmitted over the same antenna line. A digital data stream may also be transmitted by switching the supply voltage on and off or changing the voltage in accordance with the digital coding. An energy store in the antenna amplifier, e.g., a capacitor or an inductance coil, powers the antenna amplifier for the duration of the supply-voltage shutoff.

A suitable device for splitting up the signal components, such as radio signals, control information, and/or voltage supply, should be provided in the antenna amplifier. The tuning information may be derived from the oscillator voltage or the tuning voltage of the front-end filtering means. It is also conceivable for the required information to be generated with the aid of an additional or digital open-loop control block already provided in the receiver for other tasks.

In one example embodiment of the antenna amplifier, the device for splitting up the signal components also includes, at the output, a storage unit for storing tuning information. In this manner, a plurality of settings may be temporarily stored, for example, in the form of the charging of several capacitors to different voltage values, or as digital information in an open-loop control module. This is particularly advantageous when the receiving frequency should be rapidly changed or changed for a short period of time, e.g., in the case of so-called RDS skips, and the transmission of the tuning information over the antenna line occurs very slowly in comparison to this.

One further example embodiment of the antenna amplifier provides for the reactions to control signals, such as a switchover to previously stored tuning information, to occur in response to defined events or at defined times. This may be triggered via synchronization with external events, such as an incoming control signal, or internal events, such as the exceeding of a predefined temperature value. It is particularly advantageous to implement a time reference in the antenna amplifier, so that the execution may be carried out by the receiver at a predefined time, without repeated triggering. This is an additional, suitable alternative for synchronously implementing brief RDS jumps in the antenna amplifier and in the receiver.

In one further example embodiment of the antenna amplifier, additional control signals may be applied to a control terminal or to the output. Besides the transmission of the tuning information, other data may also be transmitted from the receiver to the antenna amplifier, in order to control its operating mode. Thus, e.g., the signal level measured in the receiver may be used for adjusting the amplification factor in the antenna amplifier, or the selected receiving band activates different amplifier elements, such as one for medium-frequency reception or one for very-high-frequency reception.

In one further example embodiment of the antenna amplifier, it may include a means for generating a return signal applied to the output. This return channel may be used as a receipt acknowledgment for switching commands, transmission of fault conditions such as temperature, current monitoring, and the like, or other information.

The present invention also provides a receiver having means for generating a tuning signal and/or additional control signals for an antenna amplifier. In the case of the receiver according to the present invention, it is provided that the means for generating the tuning signal and/or additional control signal include a component, whose input is connected to a microcontroller or an internal tuning signal, and to whose output the tuning signal is applied in a form that is suitable for transmission to an antenna amplifier according to the present invention. The integration of the signal processing for frequency matching of the antenna amplifier may alternatively take place in the front-end IC or in the microcontroller.

In one further example embodiment, the receiver may include means for detecting and/or evaluating information signals that are generated by the antenna amplifier and are transmitted in addition to the radio signals. These may include information about the signal level, information regarding the operating state of the antenna amplifier, or the like.

The present invention also provides a receiving system, in particular a receiving system of a motor vehicle, having a receiver and an antenna amplifier.

The antenna amplifier of the present invention, the receiver of the present invention, as well as the receiving system of the present invention, may also be used for other broadcasting standards and other stationary and mobile receiving systems. These may include, for example, mobile receivers installed in airplanes, ships, or other vehicles, or stationary receiving systems or portable mobile transceivers or the like.

### BRIEF DESCRIPTION OF THE DRAWINGS

FIG. 1 shows a block diagram of an antenna amplifier according to the present invention and a receiver according to the present invention, where tuning information is transmitted.

FIG. 2 shows a block diagram of an antenna amplifier according to the present invention and a receiver according to the present invention, where tuning information and signal-level information is transmitted.

### DETAILED DESCRIPTION

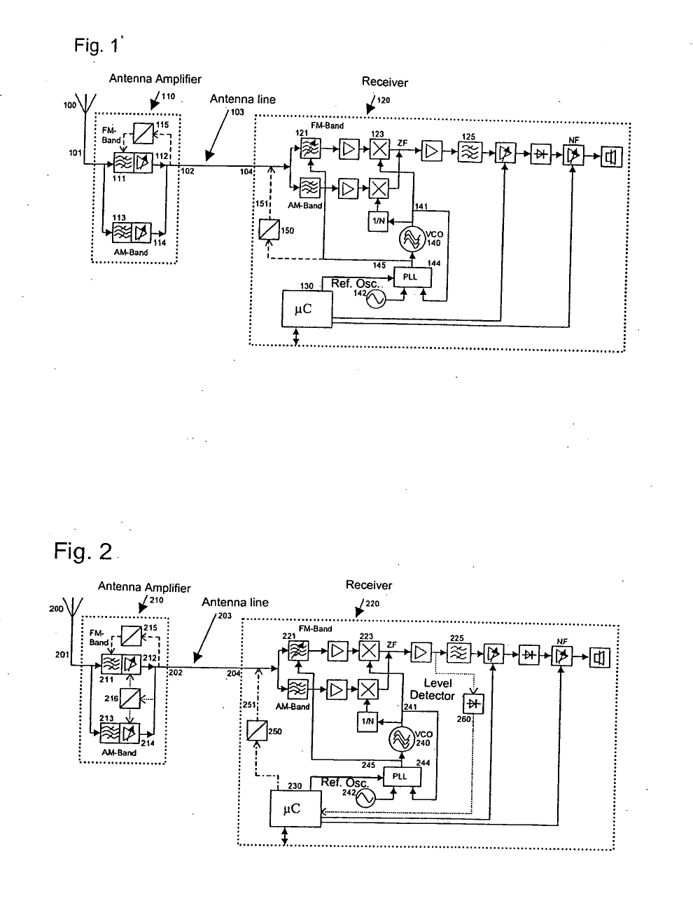

As shown in FIG. 1, a receiver 120 includes filtering means 121, which split the signal path into an FM band and an AM band, the FM filter only allowing a part of the FM band to pass through. The mid-frequency of this sub-range may be changed by a tuning voltage 145. The actual tuning to a single receiving frequency is accomplished by mixing the receiving range with an oscillator signal 141, whose frequency is changeable, and subsequently channel-filtering the intermediate-frequency signal with the aid of a filter 125. A PLL synthesizer 144 generates an oscillator-tuning voltage 145 by comparing the phase of a reference oscillator 142 to output signal 141 of mixing oscillator 140, mixing oscillator 140 being kept at a suitable frequency with the aid of the oscillator-tuning voltage 145, and the adjusted receiving channel being able to be mixed down to the intermediate frequency with the aid of the suitable frequency. An open-loop control block 150 generates a tuning signal 151 from oscillator tuning signal 145. Tuning signal 151, which contains information about the selected receiving channel and/or the receiving frequency, is applied to input 104 of receiver 120, which means that the tuning signal reaches output 102 of antenna amplifier 110 via antenna line 103.

Antenna amplifier 110 includes an input 101, to which an antenna 100 is connected. In addition, antenna amplifier 110 includes a narrow-band filter 111, as well as an active element 112 for impedance matching and/or signal amplification. In principle, the active element is an isolation amplifier, which transforms the impedance of input 101 to a different impedance of output 102 corresponding to the input impedance of receiver 120 and, in some instances, markedly amplifies the signal coming from antenna 100. In order to limit nonlinear effects in antenna amplifier 110, the level in amplifier 112 is controlled or limited. In addition to a narrow-band filter 111 for the FM band, as well as amplifier 112 for the FM band, a filter 113 is provided for the AM band, and an amplifier 114 is provided for the AM band.

Narrow-band filter 111 for the FM band is a controllable filter, i.e., the pass frequency may be shifted in the desired receiving-frequency range. A device 115 for filtering the tuning information out of the signals directed through the antenna line is used for setting the pass frequency. As an alternative, the tuning information may be provided by a device for splitting up the signal components, such as radio signals, tuning information, and voltage supply for the active parts of antenna amplifier 110. In this example, device 115 is only shown for the signal path of the FM band; the same element could be provided for the signal path of the AM band, if its filter 113 were likewise designed to have a narrow-band characteristic and to be tunable.

Device 115 evaluates the signal applied to output 102 of the antenna amplifier and adjusts narrow-band filter 111 to the receiving frequency, which is set at receiver 120. To this end, as described above, module 150 converts signals of PLL synthesizer 144 into an analog or digital tuning signal, which is applied to input 104 of receiver 120 and reaches output 102 of antenna amplifier 110, and by which the pass frequency of filter 111 is tuned to the receiving frequency of receiver 120. Output 102 may be simultaneously used, for example, to supply a d.c. voltage signal for supplying voltage to the active components of antenna amplifier 110. Therefore, by adjusting the receiving frequency of receiver 120, narrow-band filter 111 of antenna amplifier 110 is simultaneously set to a receiving frequency that is the same as the pass frequency.

Device 115 may also include means, which can temporarily store one or more settings, e.g., in the form of the charging of several capacitors to different voltage values, or as digital information in an open-loop control module. The temporarily stored information may be, in particular, information regarding one or more pass frequencies of filter 111, which means that one can easily switch back and forth between different pass frequencies.

A block diagram of a further exemplary embodiment according to the present invention is shown in FIG. 2. In comparison with the first example of FIG. 1, the following changes are provided:

In receiver 220, a level detector 260 ascertains the signal strength of the intermediate-frequency signal and transmits the information to a microcontroller 230. The microcontroller now determines if the amplification of the antenna amplifier should be reduced on the basis of a high signal level and transmits corresponding information, as well as the set receiving frequency, to module 250. The two information items are now transmitted over antenna line 203 to antenna amplifier 210 in a suitable format. The tuning information is filtered out in module 215. A module 216 extracts the amplification to be set and subsequently controls amplifier 212 and/or 214.

1-15. (canceled)

16. An antenna amplifier, comprising:
an input for connecting to an antenna;
an output for connecting to a receiver;
an arrangement for providing signal-level matching between the input and the output; and
a narrow-band filter situated between the input and the arrangement for providing signal-level matching, wherein a pass frequency of the narrow-band filter is configured to be tuned to a receive channel of the receiver.

17. The antenna amplifier as recited in claim 16, wherein the pass frequency of the narrow-band filter is tuned via a tuning signal that is generated by the receiver and applied to a control terminal of the antenna amplifier.

18. The antenna amplifier as recited in claim 16, wherein the pass frequency of the narrow-band filter is tuned via a tuning signal that is generated by the receiver and applied to the output of the antenna amplifier.

19. The antenna amplifier as recited in claim 18, wherein the tuning signal applied to the output of the antenna amplifier is evaluated in the antenna amplifier, and wherein the tuning signal is one of a d.c. voltage, an analog amplitude-modulated signal, an analog frequency-modulated signal, an analog pulse-width-modulated signal, and a digital data stream.

20. The antenna amplifier as recited in claim 18, further comprising:
a device for one of splitting up and filtering out signal components of a received signal at the output of the antenna amplifier.

21. The antenna amplifier as recited in claim 18, wherein a supply voltage for the antenna amplifier is applied to the output of the antenna amplifier.

22. The antenna amplifier as recited in claim 20, wherein the device for one of splitting up and filtering out signal components of the received signal includes a storage unit for storing tuning information.

23. The antenna amplifier as recited in claim 18, wherein further control signals are applied to one of a control terminal of the antenna amplifier and the output of the antenna amplifier.

24. The antenna amplifier as recited in claim 23, further comprising:
a return-signal generating unit for generating a return signal that is applied to one of the control terminal and the output.

25. The antenna amplifier as recited in claim 23, wherein responses to the further control signals occur at defined moments, wherein the responses include a switchover to previously stored tuning information.

26. A receiver, comprising:
a means for generating at least one of a tuning signal and additional control signals for an antenna amplifier, wherein the antenna amplifier includes:
an input for connecting to an antenna;
an output for connecting to a receiver;
an arrangement for providing signal-level matching between the input and the output; and
a narrow-band filter situated between the input and the arrangement for providing signal-level matching, wherein a pass frequency of the narrow-band filter is configured to be tuned to a receive channel of the receiver.

27. The receiver as recited in claim 26, wherein the means for generating the at least one of a tuning signal and additional control signals includes a module, and wherein an input of the module is connected to one of a microcontroller and an internal tuning signal, and wherein the tuning signal is applied to an output of the module in a form suitable for transmission to the antenna amplifier.

28. The receiver as recited in claim 26, further comprising:
means for at least one of detecting and evaluating information signals which are generated by the antenna amplifier and are transmitted in addition to radio signals.

29. A receiving system of a motor vehicle, comprising:
an antenna amplifier, wherein the antenna amplifier includes:
an input for connecting to an antenna;
an output for connecting to a receiver;
an arrangement for providing signal-level matching between the input and the output; and
a narrow-band filter situated between the input and the arrangement for providing signal-level matching, wherein a pass frequency of the narrow-band filter is configured to be tuned to a receive channel of the receiver; and
a means for generating at least one of a tuning signal and additional control signals for the antenna amplifier.
